(19) United States
(12) Patent Application Publication
(10) Pub. No.: US 2025/0374710 A1
(43) Pub. Date: Dec. 4, 2025

(54) ELECTROMAGNETIC SHIELDING CAP FOR ELECTRONIC CIRCUITS

(71) Applicant: STMicroelectronics International N.V., Geneva (CH)

(72) Inventors: Nicolas MASTROMAURO, Lumbin (FR); Karine SAXOD, Porte de Savoie (FR)

(73) Assignee: STMicroelectronics International N.V., Geneva (CH)

(21) Appl. No.: 19/214,874

(22) Filed: May 21, 2025

(30) Foreign Application Priority Data
May 30, 2024 (FR) FR2405584

(51) Int. Cl. H10F 77/30; H10F 39/95; H10F 77/50; H10H 29/01; H10H 29/20; H10H 29/85

(52) U.S. Cl. CPC H10F 77/334; H10F 39/95; H10F 77/50; H10H 29/036; H10H 29/20; H10H 29/8506

(57) ABSTRACT

An electromagnetic shielding cap for an electronic circuit includes a main surface and four lateral surfaces. A recessed portion is present in the first lateral surface provided by an open cavity in and at a base of the first lateral surface. An electronic circuit, such as an optical transmission and/or reception device, includes a chip bonded to a first main surface of a substrate. The electromagnetic shielding cap is mounted over the chip to the first main surface of the substrate. The circuit further includes an additional cap made of polymer material. The electromagnetic shielding cap is assembled to the substrate using a solder joint soldered both to a metal pad of the substrate and to at least one wall of the recessed portion. The second cap may be positioned over or under the first cap.

### PRIORITY CLAIM

This application claims the priority benefit of French Application for Patent No. FR2405584, filed on May 30, 2024, the content of which is hereby incorporated by reference in its entirety to the maximum extent allowable by law.

### TECHNICAL FIELD

The present disclosure generally concerns the field of electronic circuits and, in particular, electromagnetic shielding caps intended to protect electronic circuits, especially those including light radiation emitters and/or light radiation receivers.

### BACKGROUND

Some electronic circuits comprise an electronic integrated circuit (IC) chip housed in a package. Such a package often comprises a support portion having the chip bonded thereto, and a cover portion covering the chip. The cover is mounted on the support portion. It is, for example, made of resin.

When electronic chips comprise optical signals transmission and reception regions, the cover portion comprises, opposite the transmission/reception regions, elements transparent for the wavelengths of the optical signals and an inner wall, delimiting two cavities, one for the transmission region and one for the reception region.

Such electronic circuits are, for example, used to create time-of-flight (TOF) proximity sensors for detecting the presence or the absence of an object located in front of the package cover.

Since such electronic circuits are sensitive to electromagnetic waves, an electromagnetic shielding has to be added. For this purpose, a metal cap may be positioned on the cover. It may be bonded to the support substrate with a bead of glue.

However, due to bead calibration difficulties, there appear a number of disadvantages. There is a risk for the bonding material, interposed between the wall and the receiver chip, to flow by capillarity, into the cap, which might hinder the proper operation of the electronic component. Further, the strength of the cap bonding is uncertain.

There exists a need to provide an electronic circuit comprising an electromagnetic shielding cap, the cap having a good mechanical strength.

### SUMMARY

In an embodiment, an electronic circuit, in particular an optical transmission and/or reception device, comprises a chip bonded to a first main surface of a substrate, the first main surface of the substrate comprising at least one metal pad; a first electromagnetic shielding cap, preferably made of metal, and a second cap, preferably made of polymer material, being stacked and positioned on the first main surface of the substrate; the first cap comprising a main surface and four lateral surfaces, a recessed portion being formed at the base of a first lateral surface, the first cap and the substrate being assembled to each other by means of a solder joint, positioned in the recessed portion, soldered both to the metal pad and to at least one of the walls of the recessed portion.

According to a specific embodiment, at least one of the other lateral surfaces of the cap covers one of the flanks of the substrate.

According to a specific embodiment, the three other lateral surfaces each cover one of the flanks of the substrate.

According to a specific embodiment, the second cap is positioned between the chip and the first cap.

According to a specific embodiment, the second cap is mechanically assembled to the first cap by means of a layer of glue or of adhesive.

According to a specific embodiment, the second cap is overmolded onto the first cap.

According to a specific embodiment, the substrate comprises a plurality of metal pads, a solder joint being soldered to each metal pad and to at least one of the walls of the recessed portion.

According to a specific embodiment, the cap covers at least 80% of the surface area, preferably at least 90%, and even more preferably at least 95% of the surface area of the first surface of the substrate.

In an embodiment, a method of manufacturing an electronic circuit comprises: positioning the first electromagnetic shielding cap on the first main surface of the substrate; and assembling the first cap and the substrate to each other by means of one or a plurality of solder joints, each solder joint being positioned in the recessed portion and soldered both to a metal pad and to at least one of the walls of the recessed portion.

According to a specific embodiment, the method further comprises a step during which a second cap, preferably made of polymer material, is assembled to the first main surface of the first substrate via a bead of glue and a step during which the first cap is assembled to the second cap by means of a layer of glue or of adhesive.

According to a specific embodiment, a second cap, made of polymer material, is overmolded onto the first cap prior to positioning the first electromagnetic shielding cap.

According to a specific embodiment, the assembling is carried out by solder projection.

In an embodiment, an electromagnetic shielding cap for an electronic circuit, for example made of a metal selected from among a stainless steel or copper, comprises a main surface and four lateral surfaces, a recessed portion being formed at the base of a first lateral surface, the first lateral surface preferably having a height smaller than the height of the other lateral surfaces.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 schematically shows a cross-section and top view of an electronic circuit;

FIG. 2 schematically shows a cross-section and side view of an electronic circuit;

FIG. 3 schematically shows a cross-section and side view of an electronic circuit;

FIG. 4 schematically shows a cross-section and side view of an electronic circuit;

FIG. 5 schematically shows in three dimensions a portion of an electronic circuit; and

FIG. 6 and FIG. 7 are photographic views of a portion of the substrate and of the recessed portion of a cap of an electronic circuit, respectively, before and after jet soldering.

### DETAILED DESCRIPTION

The various elements are not necessarily all to the same scale, to make the drawings more readable.

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified “about”, “approximately”, “substantially”, and “in the order of” signify plus or minus 10% or 10°, preferably of plus or minus 5% or 5°.

By between X and Y, there is meant that limits X and Y are included in the range of values.

By radio frequency wave, there is meant an electromagnetic wave having a frequency between 3 kHz and 3,000 GHz, more particularly between 3 kHz and 6 GHz, and more particularly still 100 kHz and 6 GHz.

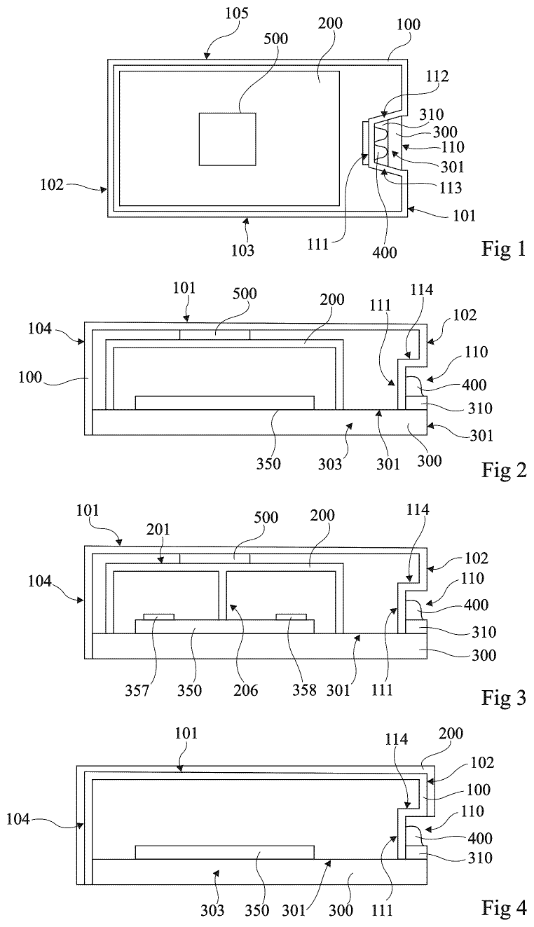

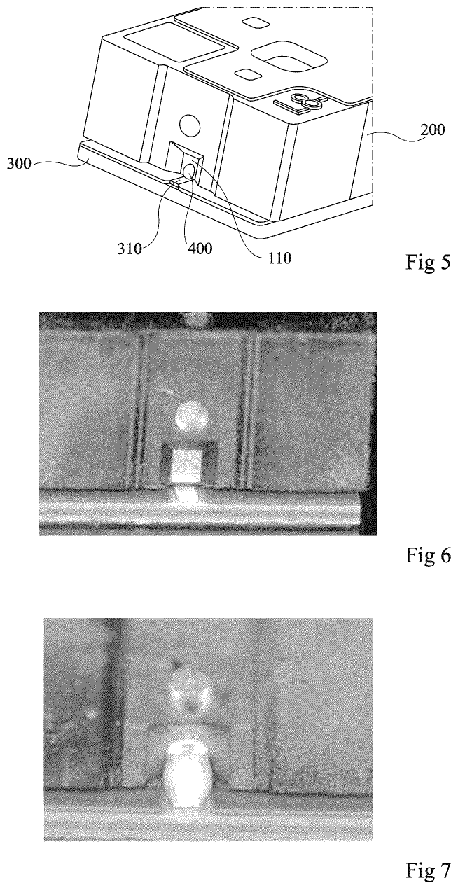

The various elements of the electronic circuit will be described in detail, referring to FIGS. 1 to 5.

The electronic circuit comprises a support substrate 300 having an electronic chip 350 positioned thereon, a first electromagnetic shielding cap 100, and a second cap 200 made of a polymer material. The first cap 100 and the second cap 200 are positioned on substrate 300 so as to protect chip 350.

The first cap 100 and the second cap 200 are stacked on each other. The first cap 100 may be positioned over or under the second cap 200.

Support substrate 300 (also referred to as a substrate or support) comprises a first main surface 301 (front surface), a second main surface 302 (rear surface) substantially parallel to the first main surface 301, and flanks 303. Flanks 303 extend from the first main surface 301 to the second main surface 302. The contour of the support substrate is, for example, square or rectangular.

The peripheral area of the first surface 301 of support substrate 300 is covered by at least one pad 310. Preferably, the peripheral area is covered by a plurality of pads 310.

Metal pads 310 may be set back from the edge of substrate 300 (FIG. 1) or arranged on the edge of the substrate (FIGS. 1 to 5).

Metal pads 310 may be arranged on two sides of the first surface in order to bond cap 100 to two sides of substrate 300. Metal pads 310 are preferably arranged on one and the same side of the first surface 301.

Pads 310 are made of an element that can be wetted by a solder material to assemble substrate 300 to the first cap 100. Pads 310 are made of a metal or of a metal alloy. Metal pads 310 are, for example, made of copper.

Support substrate 300 is made of a dielectric material. It comprises electrical connections (not shown) running from the first main surface 301 to the second main surface 302.

Substrate 300 is an interconnection substrate enabling to connect the electronic circuit to an external device or to a substrate of PCB (printed circuit board) type.

The rear surface 302 of support substrate 300 may be provided with electrical connection pads to connect the electronic circuit to an external element.

Electronic integrated circuit (IC) chip 350 (more simply called chip) 350 is arranged on support 300 and more particularly on the first main surface 301 of support substrate 300. It is, for example, arranged on a central portion of substrate 300.

Chip 350 is electrically coupled to the electrical connection network of support substrate 300 via an element ensuring the electrical connection, such as wires or balls. A glue layer (not shown) may be interposed between the front surface 301 of support substrate 300 and a rear surface of electronic chip 350.

According to an embodiment, chip 350 comprises an optical transmission (light-emitting) portion 357 and an optical reception (light-receiving) portion 358.

Light-emitting portion 357 is configured to transmit a light signal and light-receiving portion 358 is configured to detect an incident light signal. Light-emitting portion 357 and light-receiving portion 358 are intended to cooperate in such a way as to measure a distance by time of flight of the light signal transmitted and then incident after reflection.

Alternatively, two chips may be used, one being a light-emitting chip configured to transmit a light signal and the other chip being a light-receiving chip configured to detect an incident light signal.

The first cap 100 plays the role of an electromagnetic shield, particularly against radio frequencies. The first cap 100 is preferably a metal cap. It is, for example, made of stainless steel or of copper. The stainless steel is, for example, SUS430 or SUS 316L stainless steel. The first cap 100 may be nickel-plated (that is, the stainless steel or copper is coated with nickel).

The first cap 100 comprises a main surface 101 (also referred to as a front surface or upper surface) and four lateral surfaces (a first lateral surface 102, a second lateral surface 103, a third lateral surface 104, and a fourth lateral surface 105). The third lateral surface 104 and the first lateral surface 102 of the cap are opposite.

Lateral surfaces 102, 103, 104, 105 each have a base (also referred to as a foot) and an apex. The apex is located on the side of main surface 101. The base is located opposite to the apex.

A first lateral surface 102 has, at its base, a recessed portion 110. This portion 110 is recessed with respect to the first lateral surface 102.

Recessed portion 110 comprises a first wall 111 (or main wall), parallel to the first lateral surface 102 of the first cap 100, two side walls 112, 113, and a top wall 114. The side walls 112, 113 of recess 110 may be perpendicular to the first wall 111 or oblique with respect to the first wall 111. When the first cap 100 is assembled to substrate 300, the first surface 301 of substrate 300 forms the bottom wall of cavity 110. The base of the first lateral surface 102 bears on substrate 300.

Recessed portion 110 forms an open cavity having an opening at the first lateral surface 102. Recessed portion 110 is a portion recessed into cap 100; the recessed portion 110 does not form a through hole extending through the first lateral surface 102 of the first cap 100.

The first cap 100 may have two recessed portions, one on the first lateral surface 102 and one on the third lateral surface 104, for example, like that shown by portion 110.

The shape and the dimensions of recessed portion 110 depend on the shape and on the size of solder joint(s) 400. Recessed portion 110 is configured to be able to accommodate solder joint(s) 400. There is one solder joint 400 per pad 310. For example, there are two solder joints 400 in recessed portion 110.

By positioning the solder joints 400 in recessed portion 110, the bending effect of substrate 300, which could affect the mechanical strength of the solder joints 400 (and which might in particular lead to the breakage of joints 400), is limited or even nonexistent.

At least part of the surface of each pad 310 is positioned in recessed portion 110. According to a first variant, a portion only of the surface of each pad 310 is positioned in recessed portion 110 (FIG. 1). According to a second variant, the entire surface of each pad 310 (FIGS. 2 to 5) is positioned in recessed portion 110.

Once assembled, at least 80%, preferably at least 90% and even more preferably at least 95%, of the surface area of the first surface 301 of substrate 300 is covered by the first cap 100. The portion of substrate 300 not covered by the electromagnetic shielding is thus very small, which improves the performance of the electronic circuit. The electronic circuit exhibits a good mechanical strength, not only during the final tests carried out at the end of its manufacturing, but also during its operation.

The first lateral surface 102 has a first height. The second 103, third 104, and fourth 105 lateral surfaces respectively have a second, third, and fourth height. The first height is smaller than at least one of the second, third, and fourth heights. Preferably, it is smaller than the second, third, and fourth heights. Thus, during the positioning of cap 100 on substrate 300, the second 103, third 104, and fourth 105 lateral surfaces cover the flanks 303 of support substrate 300. The obtained electromagnetic shielding is thus particularly efficient.

Preferably, lateral surfaces 103, 104, 105 cover at least 50% of, even more preferably at least 80% of, and even more preferably the entire height of, the sides 303 of substrate 300.

The first cap 100 may comprise transparent elements, for example made of glass, such as lenses or filters, located opposite the optical transmission/reception regions 357, 358 of chip 350. The transparent elements of the inner cap are stacked to the transparent elements of outer cap 200.

The optical filter may be configured to be selectively transparent for a given wavelength range, typically the range comprising the wavelength of the signal transmitted by light-emitting portion 357, for example infrareds.

The first cap 100 may be manufactured by stamping.

The electronic circuit comprises, in addition to the first cap 100a, a second cap 200.

According to a first embodiment, shown in FIGS. 1 to 3, the second cap 200 is positioned between chip 350 and the first cap 100. The first cap 100 covers the second cap 200.

According to this first embodiment, the first cap 100 is the outer cap and the second cap 200 is the inner cap.

The first cap 200 forms a cavity housing chip 350.

Inner cap 200 comprises a main surface 201 (also called front surface or upper surface) and lateral surfaces.

Inner cap 200 has a contour lower than that of support substrate 300. The feet of the lateral surfaces of the second cap 200 are mechanically assembled to the first surface 301 of substrate 300. The assembly may be performed by means of a bead of glue.

Inner cap 200 may comprise one or a plurality of inner walls 206 in the form of plates (as for example shown in FIG. 3). Inner walls 206 are opaque.

Wall(s) 206 separate the optical transmission/reception regions 357, 358 from chip 350.

The upper surface of inner cap 200 is mechanically assembled to outer cap 100, for example by a layer 500 of glue or of adhesive (as shown in FIGS. 1 to 3).

According to this embodiment, second cap 200 may be made of epoxy.

According to a second embodiment, shown in FIGS. 4 to 6, the first cap 100 is positioned between the second cap 200 and chip 350.

According to this second embodiment, the first cap 100 is the inner cap and the second cap 200 is the outer cap.

The second cap 200 covers the first cap 100 except for recessed portion 110. Recessed portion 110 is thus free. It is accessible to be able to perform the assembly of the first cap 100 to substrate 100. The second cap 200 has a through opening at the recessed portion 110 of the first cap 100.

The second cap 200 may be overmolded onto the first cap 100. It is, for example, made of a thermosetting resin. For example, it is an epoxy resin. The first cap 100 and the second cap 200 form a monoblock.

According to these two embodiments, the second cap 200 may comprise transparent elements, for example made of glass, such as lenses or filters, located opposite the optical transmission/reception regions 357, 358 of chip 350.

The optical filter may be configured to be selectively transparent for a given wavelength range, typically the range comprising the wavelength of the signal transmitted by light-emitting portion 357, for example infrareds.

For these different variants and embodiments, support substrate 300 and the first cap 100 are mechanically assembled by means of solder joints 400.

More particularly, the assembly phase comprises: a first step of placing the first cap 100 into contact with support substrate 300, and more particularly with the first surface 301 of support substrate 300, which is used as a bearing surface, and a second step of bonding the first cap 100 to support substrate 300.

The bonding is performed by means of a soldering step. The solder material may be deposited by any solder paste dispensing technique. Preferably, the soldering is carried out by jet soldering, during which a solder ball jetting is performed.

To bond cap 100 and substrate 300, balls made of a solder material (in the molten state) are projected onto the surfaces to be assembled (here at the contact area between the connection pads 310 of support substrate 300 and one of the walls of recessed portion 110) and, during the cooling of the solder material, solder joints 400 are formed. Pads 310 are positioned on substrate 300 so as to be in contact with the base of main wall 111.

During the soldering, main wall 111 is wetted by the solder balls.

The recess enables to contain the propagation of the solder material. The first surface of the first lateral surface 102 is not wetted by solder joint 400. The obtained solder joint 400 has a good volume/surface ratio. The mechanical strength of solder joints 400 over time is improved.

On the side of support substrate 300, the extension of solder joint 400 is defined by the surface of pads 310 accessible from recessed portion 110.

The ball diameter is, for example, 250 μm for connection pads having a surface area of 250 μm×180 μm or of 250 μm×250 μm.

The balls are made of a solder material (or solderable material), preferably selected from among tin and a tin alloy, such as for example SnAg, SnAgCu (SAC).

As a non-limiting illustration, FIG. 6 shows an electronic circuit in which the second cap 200 is the outer cap. Cap 200 has an opening enabling to perform the soldering between the underlying metal and the metal pad 310 of substrate 300. The soldering is performed by solder projection. The obtained solder joint 400 has a good mechanical strength (FIG. 7).

With such a method, there is no need to implement an additional thermal annealing step.

Such a method is simple and inexpensive to implement.

The obtained electronic circuit has a good mechanical strength and an efficient electromagnetic shielding.

The electronic circuit is in particular an optical transmission and/or reception electronic circuit and, in particular, a time-of-flight TOF measurement device. Light-emitting portion 357 is configured to transmit a light signal. The signal comes out of inner cap 200 and of outer cap 100. A photosensitive reference surface of light-receiving portion 358 immediately detects the outgoing signal transmitted by light-emitting portion 357, so as to define a signal transmission time. The outgoing signal is intended to be reflected or scattered on an element outside outer cap 100. The reflected or scattered signal is directed towards photosensitive detection portion 358. Photoreceptive portion 358 thus detects a time of reception of the reflected signal, and the time elapsed between the transmission time and the reception time is directly proportional to the distance separating the TOF device from the external object.

Such an electronic circuit has applications, in particular, in the field of mobile telephony. It also has applications in other industrial fields.

The device is, for example, intended for the automotive industry.

The device can, for example, be used in the industrial field.

The device can also be used in the field of the Internet of things and of smart homes.

It can be used in near-field communications (NFC).

The device can also be used in the implementation of 5G networks, of data centers, and of servers.

The device is, for example, intended to be used in personal electronics, in 5G connection devices, or more generally in connected devices.

The device is, for example, intended to be used in communications equipment, or in computers and peripherals.

Various embodiments and variants have been described. The person skilled in the art will understand that certain features of these various embodiments and variants could be combined, and other variants will become apparent to the person skilled in the art.

Finally, the practical implementation of the described embodiments and variants is within the abilities of those skilled in the art, based on the indications given above.

1. An electronic circuit, comprising:
a substrate having a first main surface comprising at least one metal pad;
a chip bonded to the first main surface of the substrate;
a first cap forming an electromagnetic shielding cap; and
a second cap being stacked and positioned on the first main surface of the substrate;
wherein the first cap comprises a main surface and four lateral surfaces;
wherein a first lateral surface of said four lateral surfaces includes a recessed portion formed by an open cavity in and at a base of the first lateral surface;
a solder joint, positioned in the recessed portion, that is soldered both to the metal pad and to at least one wall of the recessed portion, said solder joint configured to assemble the first cap and the substrate to each other.

2. The electronic circuit according to claim 1, wherein the electronic circuit comprises an optical transmission and/or reception device.

3. The electronic circuit according to claim 1, wherein the first cap is made of metal and the second cap is made of polymer material.

4. The electronic circuit according to claim 1, wherein at least one other lateral surface of said four lateral surfaces of the cap has a height greater than a height of the first lateral surface and is configured to cover one flank of the substrate.

5. The electronic circuit according to claim 1, wherein three other lateral surfaces of said four lateral surfaces have heights greater than a height of the first lateral surface and are configured to cover respective flanks of the substrate.

6. The electronic circuit according to claim 1, wherein the second cap is positioned between the chip and the first cap.

7. The electronic circuit according to claim 6, wherein the second cap is mechanically assembled to the first cap by a layer of glue or adhesive.

8. The electronic circuit according to claim 1, wherein the second cap is overmolded onto the first cap.

9. The electronic circuit according to claim 1, wherein the substrate comprises a plurality of metal pads, and wherein a solder joint is soldered to each metal pad and to at least one wall of the recessed portion.

10. The electronic circuit according to claim 1, wherein the cap covers at least 80% of the surface area of the first surface of the substrate.

11. A method of manufacturing an electronic circuit, comprising:
positioning a first cap forming an electromagnetic shielding cap on a first main surface of a substrate;
assembling the first cap and the substrate to each other by forming one or more solder joints;
wherein each solder joint is positioned in a recessed portion formed by an open cavity in and at a base of a first lateral surface of the first cap; and
wherein the solder joint is soldered both to a metal pad on the first main surface and to at least one wall of the recessed portion.

12. The method according to claim 11, further comprising:
assembling a second cap to the first main surface of the substrate using a bead of glue; and
assembling the first cap to the second cap using a layer of glue or adhesive.

13. The method according to claim 12, wherein the first cap is made of metal and the second cap is made of polymer material.

14. The method according to claim 11, further comprising overmolding a second cap onto the first cap prior to positioning a first cap.

15. The method according to claim 14, wherein the first cap is made of metal and the second cap is made of polymer material.

16. The method according to claim 11, wherein assembling is carried out by performing solder projection to form said one or more solder joints.

17. An electromagnetic shielding cap for an electronic circuit, comprising:
a main surface; and
four lateral surfaces;
wherein a first lateral surface of said four lateral surfaces includes a recessed portion formed by an open cavity in and at a base of the first lateral surface; and
wherein the first lateral surface has a height smaller than a height of other lateral surfaces of said four lateral surfaces.

18. The electromagnetic shielding cap according to claim 17, wherein the electromagnetic shielding cap is made of a metal selected from the group consisting of stainless steel and copper.
